(19) United States
(12) Patent Application Publication
(10) Pub. No.: US 2025/0337400 A1
(43) Pub. Date: Oct. 30, 2025

(54) DRIVE CIRCUIT AND SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Yasuyuki FUJIWARA, Yokohama Kanagawa (JP); Yiyao LIU, Saitama Saitama (JP)

(21) Appl. No.: 18/819,058

(22) Filed: Aug. 29, 2024

(30) Foreign Application Priority Data
Apr. 30, 2024 (JP) 2024-073708

(51) Int. Cl. H03K 17/042

(52) U.S. Cl. CPC H03K 17/04206; H03K 2217/0081

(57) ABSTRACT

A drive circuit normally-off drives a transistor circuit which is constituted of a normally-on-type first transistor and a normally-off-type second transistor connected in series. A power source voltage wiring is connected between first transistor and the second transistor. The drive circuit has a diode which is disposed between a drive terminal of the first transistor and the second transistor, a third transistor which is disposed between the power source voltage wiring and the drive terminal of the first transistor, a fourth transistor which is disposed between a ground and the drive terminal of the first transistor, a fifth transistor which is disposed between the drive terminal of the first transistor and the fourth transistor, and a control circuit unit which switches states of the second, third, fourth, and fifth transistors.

### CROSS-REFERENCE TO RELATED APPLICATION

This application is based upon and claims the benefit of priority from Japanese Patent Application No. 2024-073708, filed Apr. 30, 2024, the content of which is incorporated herein by reference.

### BACKGROUND

### Field

Embodiments described herein relate to a drive circuit and a semiconductor device.

### Description of Related Art

A technology in which a transistor circuit is constituted by connecting a normally-off-type transistor to a normally-on-type transistor in series and the transistor circuit is normally-off driven is known. For example, when a half-bridge circuit is constituted by connecting two such transistor circuits described above and the half-bridge circuit is caused to perform a switching operation, there is a problem in that undershooting occurs in drive voltage of a transistor included in the transistor circuit on a higher side when the transistor circuit on a lower side is in an OFF state. Regarding this, it is known that the occurrence of undershooting in drive voltage is curbed using a Zener diode. However, there is a limit to a reaction time of the Zener diode, and there is a problem in that undershooting cannot be sufficiently curbed.

### BRIEF DESCRIPTION OF THE DRAWINGS

FIG. 1 is a circuit diagram showing a semiconductor device of a first embodiment.

FIG. 2 is a circuit diagram showing a semiconductor package of the first embodiment.

FIG. 3 is a view showing a current flowing in an external load when a transistor circuit in the semiconductor package on a higher side of the first embodiment is in an OFF state and a transistor circuit in the semiconductor package on a lower side is in an ON state.

FIG. 4 is a view showing a current flowing in the external load when the transistor circuit in the semiconductor package on the higher side of the first embodiment is in the ON state and the transistor circuit in the semiconductor package on the lower side is in the OFF state.

FIG. 5 is a timing chart showing an example of a relationship between power source voltages and gate voltages of respective transistors when the transistor circuits of the first embodiment are switched between the ON state and the OFF state.

FIG. 6 is a view showing a current flowing in the semiconductor package on the higher side when a voltage is applied between a drain terminal and a source terminal of the transistor circuit on the higher side before a power source of the semiconductor device of the first embodiment is turned on.

FIG. 7 is a view showing a current flowing when the transistor circuit on the higher side of the first embodiment is in the OFF state and the transistor circuit on the lower side is switched from the ON state to the OFF state.

FIG. 8 is a circuit diagram showing part of a semiconductor device of a second embodiment.

FIG. 9 is a circuit diagram showing part of a semiconductor device of a third embodiment.

FIG. 10 is a circuit diagram showing part of a semiconductor device of Comparative Example 1.

FIG. 11 is a circuit diagram showing part of a semiconductor device of Comparative Example 2.

### DETAILED DESCRIPTION

A drive circuit of an embodiment is a drive circuit that normally-off drives a transistor circuit which is constituted of a normally-on-type first transistor and a normally-off-type second transistor connected in series. A power source voltage wiring for applying a power source voltage is connected between the first transistor and the second transistor. The drive circuit of the embodiment has a diode in which an anode is connected to a drive terminal of the first transistor and a cathode is connected to an output terminal of the second transistor; a third transistor which is disposed between the power source voltage wiring and the drive terminal of the first transistor; a fourth transistor which is disposed between a ground, having a reference potential that becomes a reference for the power source voltage, and the drive terminal of the first transistor; a fifth transistor which is disposed between the drive terminal of the first transistor and the fourth transistor; and a control circuit unit which switches each of the second transistor, the third transistor, the fourth transistor, and the fifth transistor between an ON state and an OFF state.

Hereinafter, a drive circuit and a semiconductor device according to embodiments will be described with reference to the drawings.

### First Embodiment

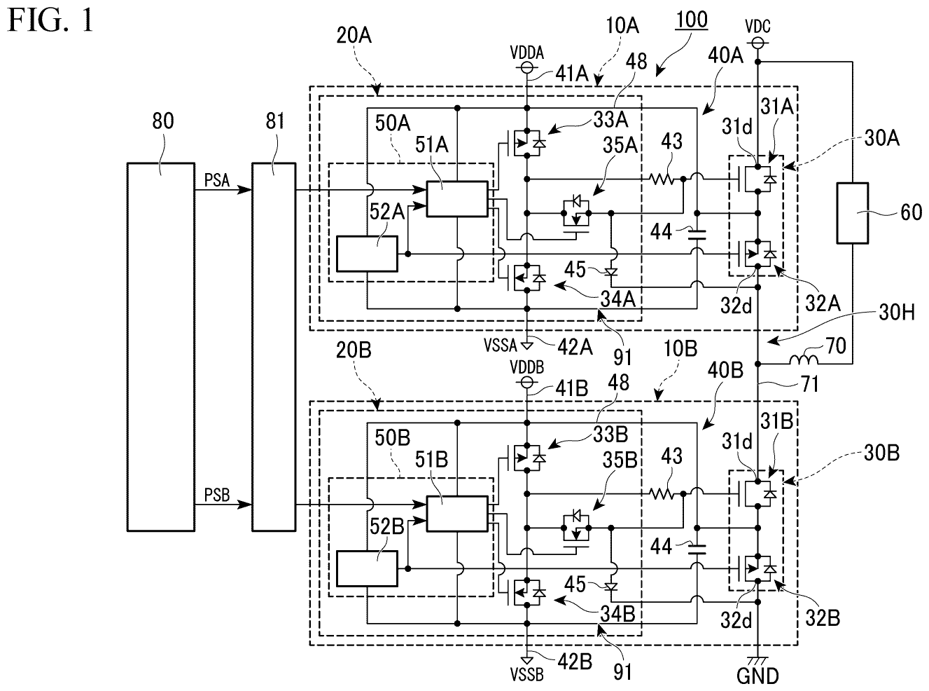

FIG. 1 is a circuit diagram showing a semiconductor device 100 of a first embodiment. The semiconductor device 100 shown in FIG. 1 is a semiconductor device for supplying power to an external load 60. The semiconductor device 100 is used as a power conversion circuit such as a power source circuit or an inverter circuit through connection to a power source, the external load 60, and a coil 70. A method for connecting the external load 60 and the coil 70 is not limited to the connection method shown in FIG. 1. The semiconductor device 100 is controlled by a controller 80. Pulse signals PSA and PSB are input to the semiconductor device 100 from the controller 80 via an insulation transfer circuit unit 81.

As shown in FIG. 1, in the first embodiment, the semiconductor device 100 includes two semiconductor packages 10A and 10B. The semiconductor package 10A and the semiconductor package 10B are provided such that they are connected to each other in series between a power source VDC for supplying power to the external load 60 and a ground GND. The semiconductor package 10A is a semiconductor package on a higher side leading to the power source VDC. The semiconductor package 10B is a semiconductor package on a lower side leading to the ground GND. In the first embodiment, the external load 60 is connected to the power source VDC in parallel to the semiconductor package 10A. The coil 70 is disposed between a wiring portion 71, which connects the semiconductor package 10A and the semiconductor package 10B, and the external load 60. The wiring portion 71 is a wiring portion connecting a transistor circuit 30A and a transistor circuit 30B which will be described below.

In the circuits of the present disclosure, “an additional element is disposed between a certain element and a different element” denotes that the additional element is provided on a circuit between the certain element and the different element in a manner of leading from one to the other.

In the first embodiment, the semiconductor package 10A and the semiconductor package 10B differ in operational timing and the like in the semiconductor device 100 but have structures which are the same as each other. For this reason, in the following description, the constitution of the semiconductor package 10A on the higher side will be described representatively, and description of the constitution of the semiconductor package 10B on the lower side may be omitted.

The semiconductor package 10A has the transistor circuit 30A and a drive circuit 40A. The semiconductor package 10B has the transistor circuit 30B and a drive circuit 40B. Each of the semiconductor packages 10A and 10B is constituted of each of the drive circuits 40A and 40B and each of the transistor circuits 30A and 30B sealed in one package. The drive circuit 40A and the transistor circuit 30A may not be sealed in one package, and the drive circuit 40B and the transistor circuit 30B may not be sealed in one package. The two transistor circuits 30A and 30B are connected to each other in series. A half-bridge circuit 30H is constituted of the two transistor circuits 30A and 30B. The transistor circuit 30A and the transistor circuit 30B are connected to each other through the wiring portion 71.

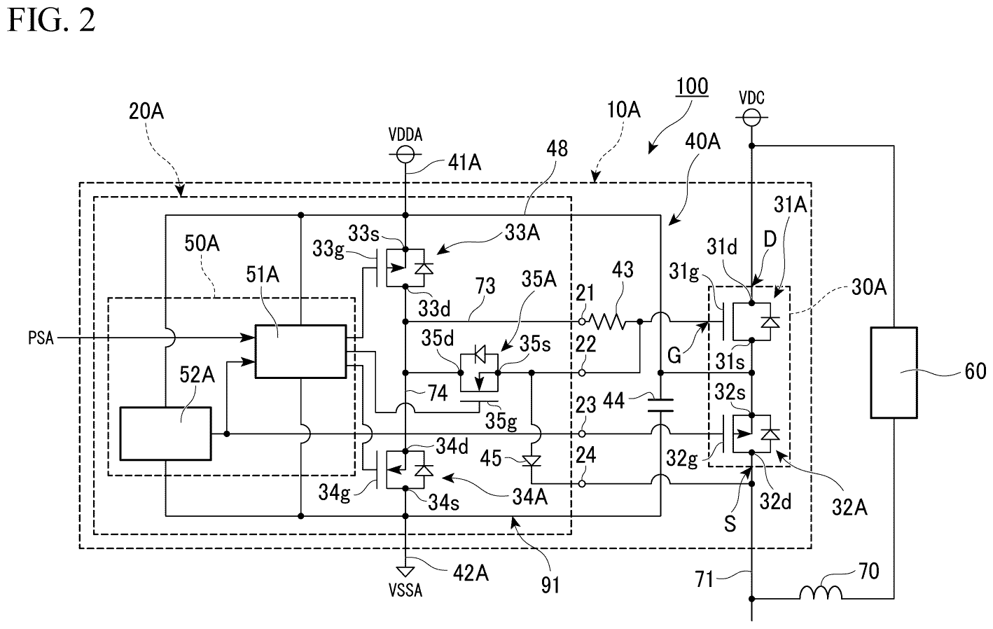

FIG. 2 is a circuit diagram showing the semiconductor package 10A. As shown in FIG. 2, the transistor circuit 30A has a constitution in which a first transistor 31A and a second transistor 32A are connected in series. The first transistor 31A is a normally-on-type transistor. The first transistor 31A is a field-effect transistor (FET). For example, the first transistor 31A is a high-electron-mobility transistor (HEMT) using gallium nitride (GaN). The first transistor 31A is a high-withstand-voltage element whose withstand voltage is approximately 600 V or higher, for example. A drain terminal 31d of the first transistor 31A is connected to the power source VDC. A source terminal 31s of the first transistor 31A is connected to a source terminal 32s of the second transistor 32A. The first transistor 31A is in an ON state when the potential difference between a gate terminal 31g and the source terminal 31s is 0 V. A threshold voltage of the first transistor 31A has a negative voltage value. In the following description, it is assumed that the threshold voltage of the first transistor 31A is −Vth, and the absolute value of the threshold voltage of the first transistor 31A is Vth. The first transistor 31A is in an OFF state if a gate voltage becomes lower than −Vth with respect to the source terminal 31s.

The second transistor 32A is a normally-off-type transistor. The second transistor 32A is a field-effect transistor. In the first embodiment, the second transistor 32A is a P channel-type field-effect transistor. More specifically, the second transistor 32A is a P channel-type metal-oxide-semiconductor field-effect transistor (MOSFET). The withstand voltage of the second transistor 32A is lower than the withstand voltage of the first transistor 31A. The second transistor 32A is a low-withstand-voltage MOSFET whose withstand voltage is approximately 50 V or lower, for example. The source terminal 32s of the second transistor 32A is connected to the source terminal 31s of the first transistor 31A. A drain terminal 32d of the second transistor 32A is connected to the wiring portion 71 connecting the two transistor circuits 30A and 30B to each other.

The transistor circuit 30A constituted of the first transistor 31A and the second transistor 32A can be regarded as one normally-off-type field-effect transistor. When the transistor circuit 30A is regarded as one field-effect transistor, a gate terminal G of the field-effect transistor is the gate terminal 31g of the first transistor 31A, a drain terminal D of the field-effect transistor is the drain terminal 31d of the first transistor 31A, and a source terminal S of the field-effect transistor is the drain terminal 32d of the second transistor 32A.

In the present disclosure, a gate terminal of a field-effect transistor corresponds to “a drive terminal”. A drive terminal of a transistor is a terminal to which a voltage is applied so as to drive the transistor. In a drain terminal and a source terminal of a field-effect transistor, the terminal on a side where a current goes out when the field-effect transistor is in the ON state corresponds to “an output terminal”. Namely, the drain terminal corresponds to “an output terminal” in a P channel-type field-effect transistor, and the source terminal corresponds to “an output terminal” in an N channel-type field-effect transistor.

In the first embodiment, the drain terminal D of the transistor circuit 30A corresponds to “a first terminal” provided in the first transistor 31A. The source terminal S of the transistor circuit 30A corresponds to “a second terminal” that is the output terminal of the second transistor 32A. In the first embodiment, the transistor circuit 30A functions as a transistor having the gate terminal G that is the drive terminal of the first transistor 31A, the drain terminal D serving as the first terminal provided in the first transistor 31A, and the source terminal S serving as the second terminal that is the output terminal of the second transistor 32A.

The drive circuit 40A is a drive circuit that normally-off drives the transistor circuit 30A. The drive circuit 40A is a gate drive circuit for applying a voltage to the gate terminal G of the transistor circuit 30A, that is, the gate terminal 31g of the first transistor 31A. The drive circuit 40A has a semiconductor chip 20A, a resistive element 43, and a capacitor 44. The semiconductor chip 20A has a power source voltage terminal 41A, a ground element 42A, connection terminals 21, 22, 23, and 24, a power source voltage wiring 48, a ground 91, a third transistor 33A, a fourth transistor 34A, a fifth transistor 35A, a diode 45, and a control circuit unit 50A.

The power source voltage terminal 41A is exposed to the outside of the semiconductor chip 20A. A power source for driving the drive circuit 40A is connected to the power source voltage terminal 41A. A power source voltage VDDA is applied to the power source voltage terminal 41A. The power source voltage wiring 48 is connected to the power source voltage terminal 41A. The power source voltage VDDA is applied to the power source voltage wiring 48. The power source voltage wiring 48 is connected between the first transistor 31A and the second transistor 32A. The power source voltage wiring 48 is connected to the source terminal 31s of the first transistor 31A and the source terminal 32s of the second transistor 32A.

The ground element 42A is exposed to the outside of the semiconductor chip 20A. A ground having a reference potential VSSA that becomes a reference for the power source voltage VDDA is connected to the ground element 42A. The reference potential VSSA is a potential that becomes a reference when the drive circuit 40A operates. Accordingly, in the drive circuit 40A, the potential of the ground 91 connected to the ground element 42A becomes the reference potential VSSA. The reference potential VSSA is not particularly limited as long as it is a potential that becomes a reference for the power source voltage VDDA.

The connection terminals 21, 22, 23, and 24 are exposed to the outside of the semiconductor chip 20A. The resistive element 43 is connected to the connection terminal 21. The gate terminal 31g of the first transistor 31A is connected to the connection terminal 22. A gate terminal 32g of the second transistor 32A is connected to the connection terminal 23. The drain terminal 32d of the second transistor 32A is connected to the connection terminal 24.

The third transistor 33A and the fourth transistor 34A are normally-off-type field-effect transistors. In the first embodiment, the third transistor 33A is a P channel-type MOSFET. In the first embodiment, the fourth transistor 34A is an N channel-type MOSFET. The third transistor 33A and the fourth transistor 34A are connected to each other in series and are disposed between the power source voltage wiring 48 and the ground 91. A source terminal 33s of the third transistor 33A is connected to the power source voltage wiring 48. A drain terminal 33d of the third transistor 33A is connected to a drain terminal 34d of the fourth transistor 34A. A source terminal 34s of the fourth transistor 34A is connected to the ground 91.

The gate terminal 31g of the first transistor 31A is connected between the third transistor 33A and the fourth transistor 34A via the resistive element 43. Accordingly, the third transistor 33A is disposed between the power source voltage wiring 48 and the gate terminal 31g of the first transistor 31A. The fourth transistor 34A is disposed between the ground 91 and the gate terminal 31g of the first transistor 31A. The resistive element 43 is disposed between the gate terminal 31g of the first transistor 31A and the third transistor 33A. One end of the resistive element 43 is connected to the gate terminal 31g of the first transistor 31A. The other end of the resistive element 43 is connected to the drain terminal 33d of the third transistor 33A.

The fifth transistor 35A is a normally-off-type field-effect transistor. In the first embodiment, the fifth transistor 35A is an N channel-type MOSFET. The fifth transistor 35A is disposed between the gate terminal 31g of the first transistor 31A and the fourth transistor 34A. A source terminal 35s of the fifth transistor 35A is connected to the gate terminal 31g of the first transistor 31A. A drain terminal 35d of the fifth transistor 35A is connected to the drain terminal 34d of the fourth transistor 34A.

An anode of the diode 45 is connected to the gate terminal 31g of the first transistor 31A and the source terminal 35s of the fifth transistor 35A. A cathode of the diode 45 is connected to the drain terminal 32d of the second transistor 32A.

The capacitor 44 is disposed between the power source voltage wiring 48 and the ground 91. One electrode of the capacitor 44 is connected to the power source voltage wiring 48. The other electrode of the capacitor 44 is connected to the ground 91.

The control circuit unit 50A is a circuit unit for switching the second transistor 32A, the third transistor 33A, the fourth transistor 34A, and the fifth transistor 35A between the ON state and the OFF state. The control circuit unit 50A is disposed between the power source voltage wiring 48 and the ground 91. The power source voltage VDDA is input to the control circuit unit 50A. The reference potential in the control circuit unit 50A is the reference potential VSSA. The control circuit unit 50A has a switching circuit unit 51A and a voltage comparison circuit unit 52A.

The switching circuit unit 51A is disposed between the power source voltage wiring 48 and the ground 91. The power source voltage VDDA is input to the switching circuit unit 51A. The reference potential in the switching circuit unit 51A is the reference potential VSSA. The pulse signal PSA is input to the switching circuit unit 51A from the controller 80 via the insulation transfer circuit unit 81. An output from the voltage comparison circuit unit 52A is input to the switching circuit unit 51A. A gate terminal 33g of the third transistor 33A, a gate terminal 34g of the fourth transistor 34A, and a gate terminal 35g of the fifth transistor 35A are connected to the switching circuit unit 51A.

In the first embodiment, the switching circuit unit 51A switches each of the third transistor 33A, the fourth transistor 34A, and the fifth transistor 35A between the ON state and the OFF state on the basis of the pulse signal PSA and an output from the voltage comparison circuit unit 52A. More specifically, the switching circuit unit 51A individually switches the state of each transistor by applying a voltage to the gate terminal 33g of the third transistor 33A, the gate terminal 34g of the fourth transistor 34A, and the gate terminal 35g of the fifth transistor 35A on the basis of the pulse signal PSA and an output from the voltage comparison circuit unit 52A.

The voltage comparison circuit unit 52A is disposed between the power source voltage wiring 48 and the ground 91. The power source voltage VDDA is input to the voltage comparison circuit unit 52A. The reference potential in the voltage comparison circuit unit 52A is the reference potential VSSA. The gate terminal 32g of the second transistor 32A is connected to the voltage comparison circuit unit 52A. The voltage comparison circuit unit 52A is a circuit unit outputting a comparison result by comparing the voltage of the power source voltage wiring 48, that is, the power source voltage VDDA with a higher voltage than the absolute value Vth of the threshold voltage of the first transistor 31A. The threshold voltage of the normally-on-type first transistor 31A has a negative value. The comparison result in the voltage comparison circuit unit 52A is output as a voltage value. The comparison result in the voltage comparison circuit unit 52A is output to the switching circuit unit 51A and the gate terminal 32g of the second transistor 32A.

As shown in FIG. 1, the transistor circuit 30B in the semiconductor package 10B on the lower side has a constitution in which a first transistor 31B and a second transistor 32B are connected in series. The first transistor 31B is a similar transistor to the first transistor 31A in the semiconductor package 10A on the higher side. The second transistor 32B is a similar transistor to the second transistor 32A in the semiconductor package 10A on the higher side. The drain terminal 31d of the first transistor 31B is connected to the drain terminal 32d of the second transistor 32A on the higher side. The drain terminal 32d of the second transistor 32B is connected to the ground GND. In the first embodiment, the transistor circuit 30B corresponds to “a switching element” which is connected to the transistor circuit 30A in series.

Similar to the transistor circuit 30A, the drain terminal 31d of the first transistor 31B in the transistor circuit 30B is a drain terminal of the transistor circuit 30B which is regarded as one field-effect transistor. In addition, the drain terminal 32d of the second transistor 32B in the transistor circuit 30B is a source terminal of the transistor circuit 30B which is regarded as one field-effect transistor. The source terminal S in the transistor circuit 30A, that is, the drain terminal 32d of the second transistor 32A is connected to the drain terminal of the transistor circuit 30B, that is, the drain terminal 31d of the first transistor 31B. Accordingly, the source terminal S of the transistor circuit 30A is connected to the transistor circuit 30B that is a switching element.

The drive circuit 40B is a drive circuit that normally-off drives the transistor circuit 30B. The drive circuit 40B is a gate drive circuit for applying a voltage to the gate terminal of the transistor circuit 30B, that is, the gate terminal of the first transistor 31B. The drive circuit 40B has a semiconductor chip 20B, the resistive element 43, and the capacitor 44. The semiconductor chip 20B has a power source voltage terminal 41B, a ground element 42B, a third transistor 33B, a fourth transistor 34B, a fifth transistor 35B, and a control circuit unit 50B. The control circuit unit 50B has a switching circuit unit 51B and a voltage comparison circuit unit 52B. The pulse signal PSB is input to the switching circuit unit 51B from the controller 80 via the insulation transfer circuit unit 81.

A power source for driving the drive circuit 40B is connected to the power source voltage terminal 41B. A power source voltage VDDB is applied to the power source voltage terminal 41B and the power source voltage wiring 48 connected to the power source voltage terminal 41B.

A ground having a reference potential VSSB that becomes a reference for the power source voltage VDDB is connected to the ground element 42B. The reference potential VSSB is a potential that becomes a reference when the drive circuit 40B operates. Accordingly, in the drive circuit 40B, the potential of the ground 91 connected to the ground element 42B becomes the reference potential VSSB.

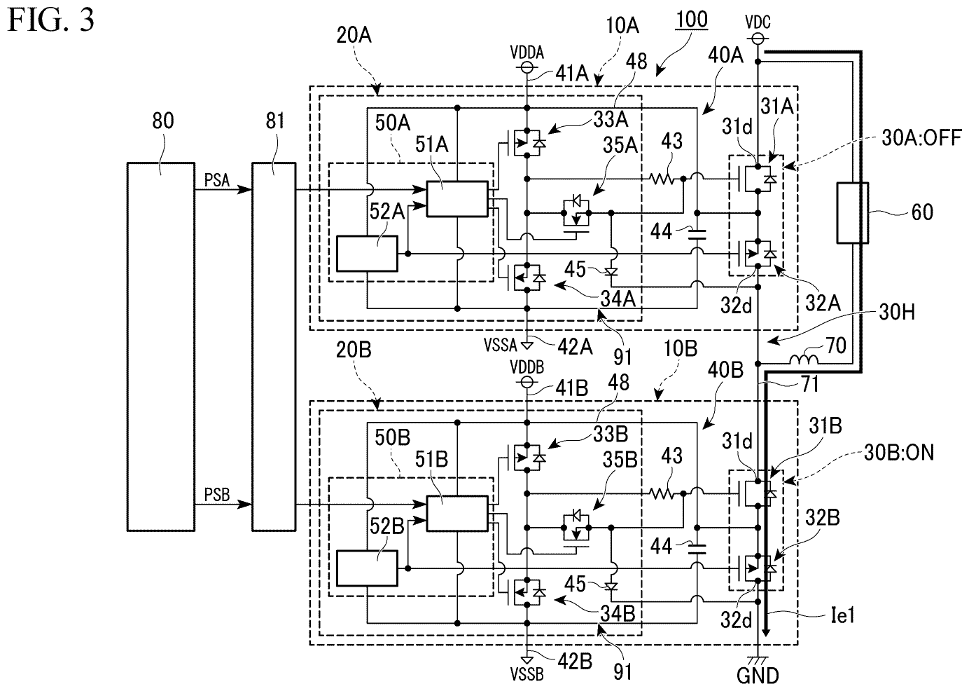

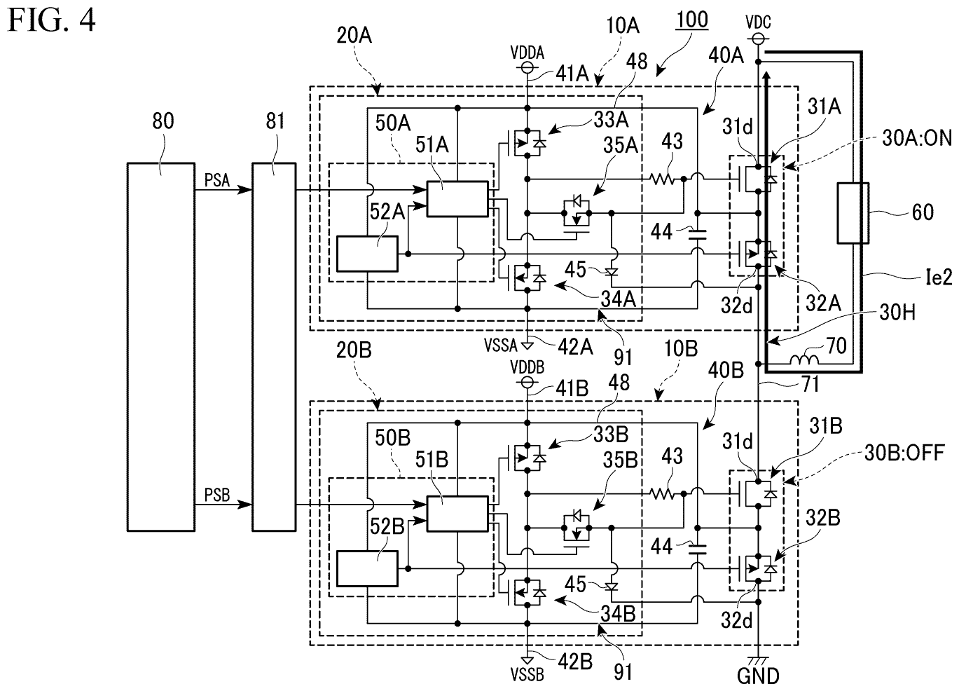

Next, operation of the semiconductor device 100 will be described. The semiconductor device 100 is controlled on the basis of the pulse signals PSA and PSB input from the controller 80. The semiconductor device 100 is controlled such that the ON/OFF state of the transistor circuit 30A in the semiconductor package 10A on the higher side and the ON/OFF state of the transistor circuit 30B in the semiconductor package 10B on the lower side are switched alternately. FIG. 3 is a view showing a current Ie1 flowing in the external load 60 when the transistor circuit 30A in the semiconductor package 10A on the higher side is in the OFF state and the transistor circuit 30B in the semiconductor package 10B on the lower side is in the ON state. FIG. 4 is a view showing a current Ie2 flowing in the external load 60 when the transistor circuit 30A in the semiconductor package 10A on the higher side is in the ON state and the transistor circuit 30B in the semiconductor package 10B on the lower side is in the OFF state.

As shown in FIG. 3, when the transistor circuit 30A on the higher side is in the OFF state and the transistor circuit 30B on the lower side is in the ON state, the current Ie1 flows from the power source VDC to the ground GND flows. The current Ie1 flows in the external load 60, the coil 70, and the transistor circuit 30B in this order from the power source VDC and flows to the ground GND. In this case, energy is stored in the coil 70.

As shown in FIG. 4, when the transistor circuit 30A on the higher side is in the ON state and the transistor circuit 30B on the lower side is in the OFF state, the current Ie2 circulating in a closed circuit constituted of the external load 60, the coil 70, and the transistor circuit 30A flows. At this time, the current Ie2 flows in the external load 60, the coil 70, and the transistor circuit 30A in this order. In addition, at this time, stored energy is discharged from the coil 70.

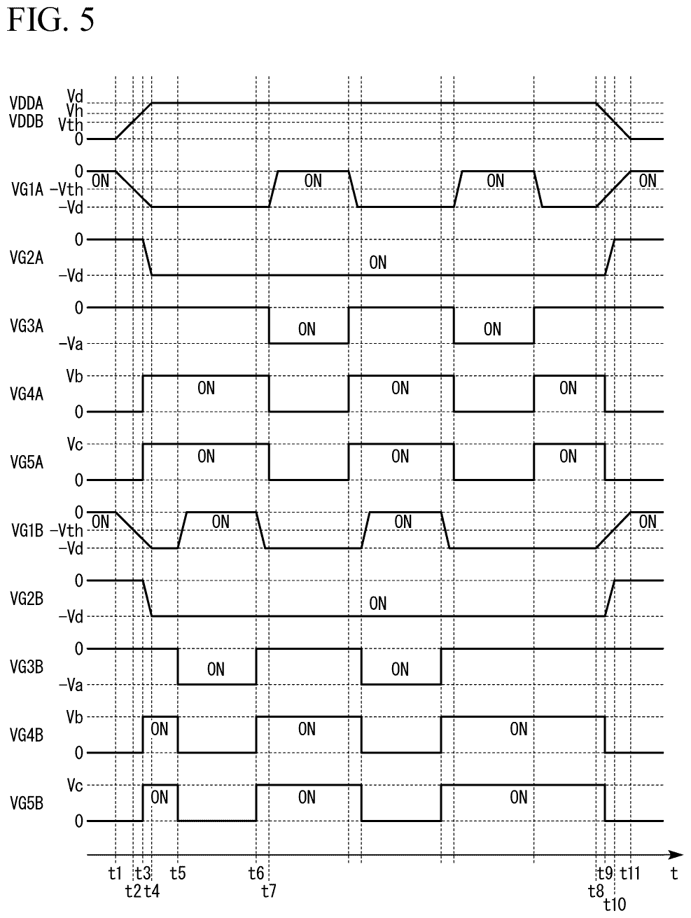

FIG. 5 is a timing chart showing an example of a relationship between the power source voltages VDDA and VDDB and the gate voltages of respective transistors when the transistor circuits 30A and 30B are switched between the ON state and the OFF state. In the following description, the power source voltage VDDA and the power source voltage VDDB may be collectively referred to as the power source voltage VDD. In addition, the reference potential VSSA and the reference potential VSSB may be collectively referred to as the reference potential VSS. VG1A is a gate voltage of the first transistor 31A. VG2A is a gate voltage of the second transistor 32A. VG3A is a gate voltage of the third transistor 33A. VG4A is a gate voltage of the fourth transistor 34A. VG5A is a gate voltage of the fifth transistor 35A. VG1B is a gate voltage of the first transistor 31B. VG2B is a gate voltage of the second transistor 32B. VG3B is a gate voltage of the third transistor 33B. VG4B is a gate voltage of the fourth transistor 34B. VG5B is a gate voltage of the fifth transistor 35B. The gate voltage is a voltage of the gate terminal with respect to the potential of the source terminal. The gate voltage corresponds to “a drive voltage” for driving the field-effect transistor.

The horizontal axis shown in FIG. 5 indicates a time t. FIG. 5 shows an example when the power source of the semiconductor device 100 is turned on at a time t1. When the power source of the semiconductor device 100 is turned off, the potential of the power source voltage wiring 48 becomes the same as the reference potential VSS, and therefore the power source voltage VDD is 0 V. When the power source of the semiconductor device 100 is turned off, the potentials of the gate terminals 31g of the first transistors 31A and 31B are the reference potential VSS, and therefore the potentials of the source terminals 31s of the first transistors 31A and 31B are also the potential of the power source voltage wiring 48, that is, the reference potential VSS. For this reason, when the power source of the semiconductor device 100 is turned off, the normally-on-type first transistors 31A and 31B are in the ON state. When the power source of the semiconductor device 100 is turned off, other normally-off-type transistors are in the OFF state. The circuit may be constituted such that the fourth transistors 34A and 34B are in the ON state when the power source of the semiconductor device 100 is turned off.

If the power source of the semiconductor device 100 is turned on, the power source voltage VDD rises from 0 V to a constant voltage Vd. If the power source voltage VDD rises, the potentials of the source terminals 31s of the first transistors 31A and 31B leading to the power source voltage wiring 48 rise. For this reason, the gate voltages VG1A and VG1B of the first transistors 31A and 31B fall by an amount corresponding to the rise in the potential of the source terminal 31s. The value of the power source voltage VDD becomes the same as the absolute value Vth of the threshold voltage of the first transistors 31A and 31B at a time t2 later than the time t1. At the time t2, the gate voltages VG1A and VG1B become the threshold voltage of the first transistors 31A and 31B, that is, −Vth. After the time t2, if the gate voltages VG1A and VG1B become lower than −Vth, the first transistors 31A and 31B are in the OFF state. At a time t4 later than the time t2, the power source voltage VDD becomes the constant voltage Vd, and the absolute value of the gate voltages VG1A and VG1B becomes the same negative value as the constant voltage Vd, that is, −Vd.

The voltage comparison circuit units 52A and 52B cause the gate voltages VG2A and VG2B to be 0 V by applying the same voltage as that of the source terminal 32s to the gate terminals 32g of the second transistors 32A and 32B and maintain the second transistors 32A and 32B in the OFF state until the power source voltage VDD exceeds the absolute value Vth of the threshold voltage of the first transistors 31A and 31B. In the first embodiment, the voltage comparison circuit units 52A and 52B cause the gate voltages VG2A and VG2B to be 0 V by short-circuiting the power source voltage wiring 48 and the gate terminals 32g of the second transistors 32A and 32B until the power source voltage VDD exceeds the absolute value Vth of the threshold voltage of the first transistors 31A and 31B.

If the power source voltage VDD becomes equal to or higher than a value Vh which is higher than the absolute value Vth of the threshold voltage of the first transistors 31A and 31B, the voltage comparison circuit units 52A and 52B decrease the voltage applied to the gate terminals 32g of the second transistors 32A and 32B and cause the P channel-type second transistors 32A and 32B to be in the ON state. In the example of FIG. 5, at a time t3 between the time t2 and the time t4, the power source voltage VDD reaches the value Vh. If the power source voltage VDD becomes equal to or higher than the value Vh, for example, the voltage comparison circuit units 52A and 52B connect the gate terminals 32g of the second transistors 32A and 32B to the ground 91. Accordingly, the gate voltages VG2A and VG2B of the second transistors 32A and 32B fall as much as the absolute value of the power source voltage VDD. If the value of the power source voltage VDD reaches the constant voltage Vd, the values of the gate voltages VG2A and VG2B of the second transistors 32A and 32B become −Vd. The threshold voltage of the second transistors 32A and 32B is a value higher than −Vd. For this reason, in the first embodiment, if the values of the gate voltages VG2A and VG2B become −Vd, the P channel-type second transistors 32A and 32B are in the ON state. In a state in which the power source voltage VDD is the constant voltage Vd, the second transistors 32A and 32B are maintained in the ON state at all times. In this manner, when the voltage of the power source voltage wiring 48 is higher than the absolute value Vth of the threshold voltage of the first transistor 31A, the control circuit unit 50A causes the second transistor 32A to be in the ON state.

If it is judged that the power source voltage VDD has exceeded the absolute value Vth of the threshold voltage of the first transistors 31A and 31B on the basis of an output from the voltage comparison circuit units 52A and 52B, the switching circuit units 51A and 51B cause the fourth transistors 34A and 34B and the fifth transistors 35A and 35B to be in the ON state by applying a voltage equal to or higher than the threshold voltage of each transistor to the gate terminals 34g of the fourth transistors 34A and 34B and the respective gate terminals 34g and 35g of the fifth transistors 35A and 35B. In the example of FIG. 5, when the power source voltage VDD reaches the value Vh higher than the absolute value Vth at the time t3, the switching circuit units 51A and 51B cause the fourth transistors 34A and 34B and the fifth transistors 35A and 35B to be in the ON state by causing the values of the gate voltages VG4A and VG4B of the fourth transistors 34A and 34B to be Vb and causing the values of the gate voltages VG5A and VG5B of the fifth transistors 35A and 35B to be Vc. The value Vb and the value Vc are not particularly limited as long as they are values of the gate voltages capable of causing the respective transistors to be in the ON state. They may be values which are the same as each other or may be values different from each other. The value Vb and the value Vc may be values which are the same as the constant voltage Vd.

If the power source voltage VDD becomes the constant voltage Vd at the time t4, the semiconductor device 100 is in an operable state. At the time t4 when the semiconductor device 100 is in an operable state, the first transistors 31A and 31B and the third transistors 33A and 33B are in the OFF state, and the second transistors 32A and 32B, the fourth transistors 34A and 34B, and the fifth transistors 35A and 35B are in the ON state. At the time t4, the same voltage as the power source voltage VDD is applied to the gate terminals 33g of the third transistors 33A and 33B from the switching circuit units 51A and 51B. Accordingly, the gate voltages VG3A and VG3B of the third transistors 33A and 33B are 0 V at the time t4, and the normally-off-type third transistors 33A and 33B are in the OFF state. When the third transistors 33A and 33B are caused to be in the OFF state, for example, the switching circuit units 51A and 51B short-circuit the gate terminals 33g and the source terminals 33s of the third transistors 33A and 33B via the power source voltage wiring 48.

The transistor circuit 30A, which is regarded as a single normally-off-type transistor, is in the ON state when both the first transistor 31A and the second transistor 32A are in the ON state, and is in the OFF state when at least one of the first transistor 31A and the second transistor 32A is in the OFF state. The same also applies to the transistor circuit 30B. For this reason, at the time t4 when the semiconductor device 100 is in an operable state, each of the transistor circuits 30A and 30B is in the OFF state. Since the second transistors 32A and 32B are in the ON state at all times while the constant voltage Vd is supplied to the semiconductor device 100 and it is in an operable state, each of the transistor circuits 30A and 30B can be turned on and off by turning on and off the states of the first transistors 31A and 31B.

If the semiconductor device 100 is in an operable state, the semiconductor device 100 starts a switching operation of alternately switching the ON/OFF states of the transistor circuit 30A and the transistor circuit 30B on the basis of the pulse signals PSA and PSB input from the controller 80. In the example of FIG. 5, at a time t5 later than the time t4, the pulse signal PSB for causing the transistor circuit 30B on the lower side to be in the ON state is input to the switching circuit unit 51B on the lower side. The switching circuit unit 51B causes the third transistor 33B to be in the ON state and causes the fourth transistor 34B to be in the OFF state on the basis of the pulse signal PSB. Specifically, the switching circuit unit 51B applies a voltage for causing the third transistor 33B to be in the ON state to the gate terminal 33g of the third transistor 33B and applies a voltage for causing the fourth transistor 34B to be in the OFF state to the gate terminal 34g of the fourth transistor 34B. In the example of FIG. 5, at the time t5, the switching circuit unit 51B causes the third transistor 33B to be in the ON state by causing the value of the gate voltage VG3B of the P channel-type third transistor 33B to be −Va and causes the fourth transistor 34B to be in the OFF state by causing the value of the gate voltage VG4B of the N channel-type fourth transistor 34B to be 0 V.

If the third transistor 33B is in the ON state and the fourth transistor 34B is in the OFF state, the gate terminal 31g of the first transistor 31B is in a state of being short-circuited with respect to the power source voltage wiring 48 via the third transistor 33B, and the gate voltage VG1B of the first transistor 31B becomes 0 V. Accordingly, the first transistor 31B is in the ON state. If the first transistor 31B is in the ON state, the transistor circuit 30B on the lower side is in the ON state, thereby being in a state in which the current Ie1 flows as shown in FIG. 3.

The switching circuit unit 51B switches the ON state and the OFF state of the fifth transistor 35B in response to switching between the ON state and the OFF state of the fourth transistor 34B. For this reason, when the fourth transistor 34B is caused to be in the OFF state at the time t5 on the basis of the pulse signal PSB, the switching circuit unit 51B also causes the fifth transistor 35B to be in the OFF state together with the fourth transistor 34B. Specifically, the switching circuit unit 51B applies a voltage for causing the fifth transistor 35B to be in the OFF state to the gate terminal 35g of the fifth transistor 35B. In the example of FIG. 5, at the time t5, the switching circuit unit 51B causes the fifth transistor 35B to be in the OFF state by causing the value of the gate voltage VG5B of the N channel-type fifth transistor 35B to be 0 V.

When the fourth transistor 34B is caused to be in the ON state on the basis of the pulse signal PSB, the switching circuit unit 51B also causes the fifth transistor 35B to be in the ON state together with the fourth transistor 34B. In this manner, the control circuit units 50A and 50B respectively cause the fifth transistors 35A and 35B to be in the ON state when the voltage of the power source voltage wiring 48 is higher than the absolute value Vth of the threshold voltage of the first transistors 31A and 31B and when the fourth transistors 34A and 34B are in the ON state.

If a predetermined time has elapsed after the transistor circuit 30B on the lower side is in the ON state and it becomes a time t6, the pulse signal PSB for instructing the transistor circuit 30B on the lower side to be in the OFF state is input to the switching circuit unit 51B from the controller 80. At the time t6, the switching circuit unit 51B causes the third transistor 33B to be in the OFF state and causes the fourth transistor 34B and the fifth transistor 35B to be in the ON state on the basis of the pulse signal PSB. Accordingly, the first transistor 31B is in the OFF state again, and the transistor circuit 30B is in the OFF state.

The controller 80 outputs the pulse signal PSA for causing the transistor circuit 30A on the higher side to be in the ON state at a time t7 after the elapse of a predetermined dead time after the transistor circuit 30B is caused to be in the OFF state at the time t6. The pulse signal PSA is input to the switching circuit unit 51A on the higher side, and the switching circuit unit 51A, similar to the switching circuit unit 51B described above, causes the transistor circuit 30A on the higher side to be in the ON state. Accordingly, the current Ie2 is in a flowing state as shown in FIG. 4. Thereafter, similarly, the state of the transistor circuit 30A and the state of the transistor circuit 30B are switched alternately.

If the power source of the semiconductor device 100 is turned off, the power source voltage VDD decreases to 0 V from the constant voltage Vd. The example of FIG. 5 shows a case in which the power source of the semiconductor device 100 is turned off at a time t8. If the power source of the semiconductor device 100 is turned off, the power source voltage VDD falls, and the gate voltages VG1A and VG1B of the first transistors 31A and 31B rise by an amount corresponding to the fall in the power source voltage VDD. If the value of the power source voltage VDD reaches the value Vh higher than the absolute value Vth of the threshold voltage of the first transistors 31A and 31B at a time t9 later than the time t8, the voltage comparison circuit units 52A and 52B cause the voltage applied to the gate terminals 32g of the second transistors 32A and 32B to be a voltage for causing the second transistors 32A and 32B to be in the OFF state. For example, the voltage comparison circuit units 52A and 52B cause the second transistors 32A and 32B to be in the OFF state by short-circuiting the gate terminal 32g and the source terminal 32s via the power source voltage wiring 48 and causing the gate voltages VG2A and VG2B of the second transistors 32A and 32B to be 0 V. When the power source of the semiconductor device 100 is turned off, the second transistors 32A and 32B cause the second transistors 32A and 32B to be in the OFF state before the power source voltage VDD reaches the absolute value Vth of the threshold voltage of the first transistors 31A and 31B.

As described above, the control circuit units 50A and 50B cause the second transistors 32A and 32B to be in the ON state after the power source voltage VDD has exceeded the absolute value Vth of the threshold voltage of the first transistors 31A and 31B when the power source of the semiconductor device 100 is turned on, and cause the second transistors 32A and 32B to be in the OFF state before the power source voltage VDD becomes equal to or lower than the absolute value Vth of the threshold voltage of the first transistors 31A and 31B when the power source of the semiconductor device 100 is turned off. Accordingly, when the power source of the semiconductor device 100 is turned on and when the power source of the semiconductor device 100 is turned off, the transistor circuits 30A and 30B are not in the ON state so that a current can be prevented from unintentionally flowing in the external load 60.

When the power source of the semiconductor device 100 is turned off, if the power source voltage VDD decreases and reaches the value Vh, the switching circuit units 51A and 51B cause the fourth transistors 34A and 34B and the fifth transistors 35A and 35B to be in the OFF state. At this time, the switching circuit units 51A and 51B may maintain the fourth transistors 34A and 34B in the ON state.

At a time t10 later than the time t9, the power source voltage VDD falls to the absolute value Vth of the threshold voltage of the first transistors 31A and 31B. If the power source voltage VDD becomes equal to or lower than the absolute value Vth of the threshold voltage of the first transistors 31A and 31B, the gate voltages VG1A and VG1B of the first transistors 31A and 31B become equal to or higher than the threshold voltage, and the first transistors 31A and 31B are in the ON state. As described above, since the second transistors 32A and 32B are in the OFF state before the power source voltage VDD reaches the absolute value Vth, even if the first transistors 31A and 31B are in the ON state, the transistor circuits 30A and 30B are maintained in the OFF state. If the power source voltage VDD becomes 0 V at a time t11, the semiconductor device 100 stops.

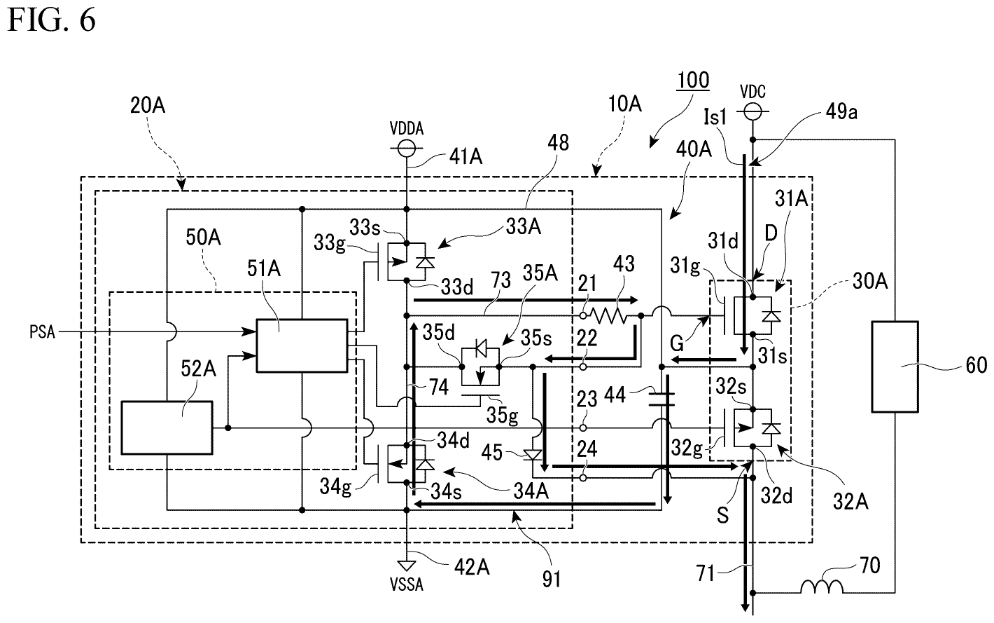

Next, a current Is1 flowing when a voltage is applied between the drain terminal D and the source terminal S of the transistor circuit 30A on the higher side before the power source of the semiconductor device 100 is turned on will be described. FIG. 6 is a view showing the current Is1 flowing in the semiconductor package 10A on the higher side when a voltage is applied between the drain terminal D and the source terminal S of the transistor circuit 30A on the higher side before the power source of the semiconductor device 100 is turned on. A case in which a voltage is applied between the drain terminal D and the source terminal S of the transistor circuit 30A on the higher side before the power source of the semiconductor device 100 is turned on indicates, for example, a case in which the power source VDC is turned on before the power source of the semiconductor device 100 is turned on. In the following description, regarding the case in which a voltage is applied between the drain terminal D and the source terminal S of the transistor circuit 30A on the higher side before the power source of the semiconductor device 100 is turned on, a case when the power source VDC is started up will be described as an example.

As shown in FIG. 6, when the power source VDC is started up, the current Is1 flows between the drain terminal 31d and the source terminal 31s of the first transistor 31A in the ON state from the drain terminal D. The current Is1 which has flowed in the first transistor 31A flows in the capacitor 44, the body diode of the fourth transistor 34A, the resistive element 43, and the diode 45 in this order from the source terminal 31s and flows to the source terminal S of the transistor circuit 30A. At this time, since the current Is1 flows in the resistive element 43, the value of the current Is1 decreases in accordance with the resistance value of the resistive element 43 so that generation of an inrush current can be curbed when the power source VDC is started up. The current Is1 is a current from the drain terminal D in the transistor circuit 30A toward the source terminal S in the transistor circuit 30A through the drive circuit 40A.

During a period before the capacitor 44 is charged by the voltage applied between the drain terminal D and the source terminal S, a potential difference occurs between the electrodes of the capacitor 44, and the current Is1 flows in the capacitor 44. The current Is1 is generated during a period until the capacitor 44 is charged.

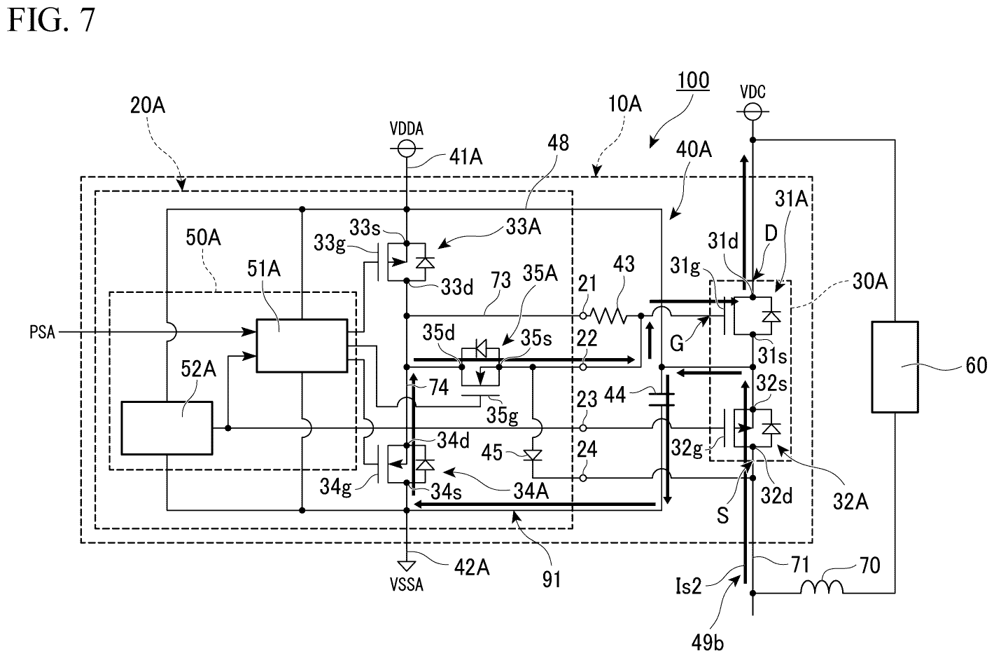

Next, a current Is2 flowing when the transistor circuit 30A on the higher side is in the OFF state and the transistor circuit 30B on the lower side is switched from the ON state to the OFF state while the semiconductor device 100 is in switching operation will be described. FIG. 7 is a view showing the current Is2 flowing when the transistor circuit 30A on the higher side is in the OFF state and the transistor circuit 30B on the lower side is switched from the ON state to the OFF state.

As shown in FIG. 7, if the transistor circuit 30B on the lower side is switched to the OFF state, the current Is2 flows from the source terminal S of the transistor circuit 30A to the second transistor 32A. The current Is2 flows from the drain terminal 32d of the second transistor 32A to the source terminal 32s. The current Is2 which has flowed in the second transistor 32A flows in the capacitor 44, the fourth transistor 34A, the fifth transistor 35A, and the gate-drain capacitance of the first transistor 31A in this order from the source terminal 32s and flows to the drain terminal D of the transistor circuit 30A. At this time, since the transistor circuit 30A on the higher side is in the OFF state and the fourth transistor 34A and the fifth transistor 35A are in the ON state, even if the current Is2 flows in the fourth transistor 34A and the fifth transistor 35A, the occurrence of a voltage fall is curbed. Accordingly, a significant drop of the voltage of the gate terminal 31g of the first transistor 31A connected to the source terminal 35s of the fifth transistor 35A is curbed, and the occurrence of undershooting in the gate voltage VG1A of the first transistor 31A is curbed. The current Is2 is a current from the source terminal S in the transistor circuit 30A toward the drain terminal D in the transistor circuit 30A through the drive circuit 40A and the gate terminal 31g of the first transistor 31A.

As shown in FIG. 4, if the transistor circuit 30B on the lower side is in the OFF state, the current Ie2 flows in the transistor circuit 30A on the higher side from the source terminal S to the drain terminal D. The current Ie2 also flows during a dead time before the transistor circuit 30A on the higher side is caused to be in the ON state immediately after the transistor circuit 30B on the lower side is caused to be in the OFF state. When the transistor circuit 30A is in the OFF state, the first transistor 31A is in the OFF state, and therefore the current Ie2 flowing in the first transistor 31A from the source terminal 31s to the drain terminal 31d flows in the body diode of the first transistor 31A. For this reason, a forward voltage of the body diode is generated between the source terminal 31s and the drain terminal 31d of the first transistor 31A. Due to the voltage, the current Is2 flowing from the source terminal 31s to the drain terminal 31d of the first transistor 31A without going through the body diode of the first transistor 31A is generated. The current Is2 is generated during a period until the capacitor 44 and the gate-drain capacitance of the first transistor 31A are charged.

If the transistor circuit 30A on the higher side is switched to the ON state from the state in which the current Ie2 flows during the dead time before the transistor circuit 30A on the higher side is caused to be in the ON state immediately after the transistor circuit 30B on the lower side is caused to be in the OFF state, the first transistor 31A is in the ON state, and a loss of the current Ie2 flowing in the first transistor 31A decreases.

In the first embodiment, the path in which the current Is1 described above flows is a first path 49a, and the path in which the current Is2 described above flows is a second path 49b. In the drive circuit 40A, when a voltage is applied between the drain terminal D and the source terminal S in the transistor circuit 30A before the power source of the semiconductor device 100 is turned on, the path in which the current Is1 flows becomes the first path 49a, and during a switching operation of the transistor circuit 30A and the transistor circuit 30B, when the transistor circuit 30B is in the OFF state, the state is switched such that the path in which the current Is2 flows becomes the second path 49b.

The resistance value in the first path 49a is equal to or larger than the resistance value of the resistive element 43. The resistance value in the first path 49a is the total resistance value while the current Is1 flows in the first path 49a from the drain terminal D in the transistor circuit 30A to the source terminal S in the transistor circuit 30A. In the first embodiment, since the first path 49a includes the resistive element 43 and elements other than the resistive element 43, the resistance value of the first path 49a becomes larger than the resistance value of the resistive element 43.

The resistance value in the second path 49b from the source terminal S to the gate terminal 31g of the first transistor 31A is smaller than the resistance value of the resistive element 43 connected to the gate terminal 31g of the first transistor 31A. The resistance value in the second path 49b from the source terminal S to the gate terminal 31g of the first transistor 31A is the total resistance value while the current Is2 flows in the second path 49b from the source terminal S in the transistor circuit 30A to the gate terminal G in the transistor circuit 30A, that is, the gate terminal 31g of the first transistor 31A.

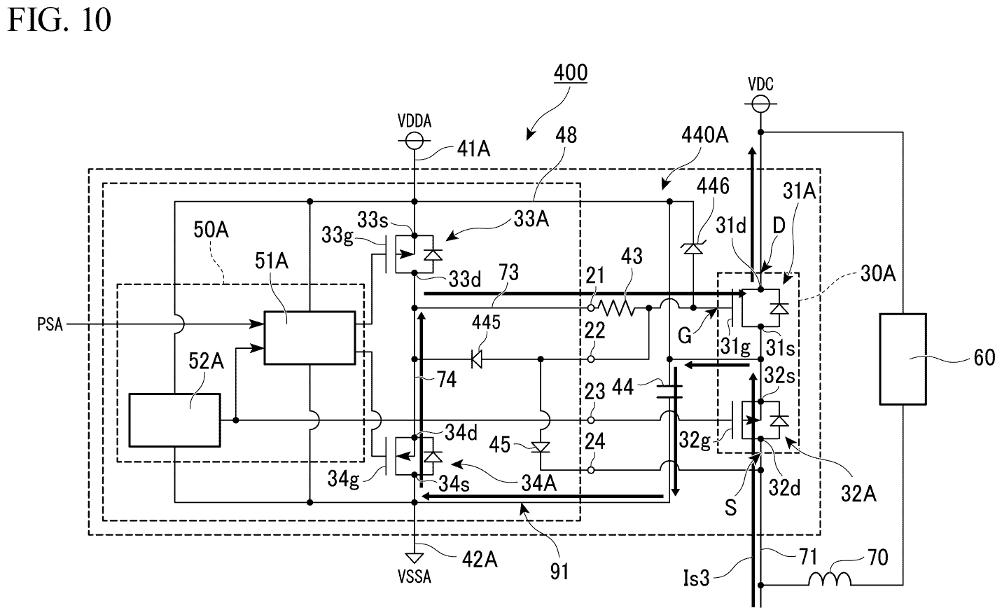

FIG. 10 is a circuit diagram showing part of a semiconductor device 400 of Comparative Example 1. In the description of Comparative Example 1, the same reference signs are suitably applied to constitutions similar to those in the first embodiment, and description may be omitted. As shown in FIG. 10, in a drive circuit 440A of the semiconductor device 400 of Comparative Example 1, a diode 445 is provided in place of the fifth transistor 35A in the semiconductor device 100 described above. An anode of the diode 445 is connected to the gate terminal 31g of the first transistor 31A. A cathode of the diode 445 is connected to the drain terminal 34d of the fourth transistor 34A.

In the semiconductor device 400 of Comparative Example 1, since a current Is3 flowing when the transistor circuit 30B on the lower side is switched to the OFF state cannot flow in the diode 445, it flows in the resistive element 43 and flows to the gate terminal 31g of the first transistor 31A. Due to the current Is3 flowing in the resistive element 43, a voltage fall occurs, and undershooting occurs in the gate voltage VG1A of the first transistor 31A. For this reason, in the semiconductor device 400 of Comparative Example 1, the occurrence of undershooting in the gate voltage VG1A is curbed by providing a Zener diode 446 in the drive circuit 440A. An anode of the Zener diode 446 is connected to the gate terminal 31g of the first transistor 31A. A cathode of the Zener diode 446 is connected to the power source voltage wiring 48. However, there is a limit to a reaction time of the Zener diode 446, and there is a limit to the effect of curbing undershooting by the Zener diode 446. Therefore, in the semiconductor device 400 of Comparative Example 1, there is a problem in that undershooting occurring in the gate voltage VG1A of the first transistor 31A cannot be sufficiently curbed.

Regarding the foregoing problems, according to the first embodiment, the drive circuit 40A is a drive circuit that normally-off drives the transistor circuit 30A constituted of the normally-on-type first transistor 31A and the normally-off-type second transistor 32A which are connected in series. The power source voltage wiring 48 for applying the power source voltage VDD is connected between the first transistor 31A and the second transistor 32A. The drive circuit 40A includes the diode 45 in which the anode is connected to the gate terminal (drive terminal) 31g of the first transistor 31A and the cathode is connected to the drain terminal (output terminal) 32d of the second transistor 32A; the third transistor 33A which is disposed between the power source voltage wiring 48 and the gate terminal 31g of the first transistor 31A; the fourth transistor 34A which is disposed between the ground 91, having the reference potential VSS that becomes a reference for the power source voltage VDD, and the gate terminal 31g of the first transistor 31A; the fifth transistor 35A which is disposed between the gate terminal 31g of the first transistor 31A and the fourth transistor 34A; and the control circuit unit 50A which switches each of the second transistor 32A, the third transistor 33A, the fourth transistor 34A, and the fifth transistor 35A between the ON state and the OFF state. For this reason, by causing the fifth transistor 35A to be in the ON state when the transistor circuit 30B on the lower side is switched to the OFF state, as shown in FIG. 7, the current Is2, after flowing from the power source voltage wiring 48 to the fourth transistor 34A via the ground 91, flows in the fifth transistor 35A in the ON state in which the resistance value is lower than that of the resistive element 43 and flows to the gate terminal 31g of the first transistor 31A. Accordingly, the occurrence of a voltage fall can be curbed during a period until the current Is2 flows to the gate terminal 31g. Therefore, the occurrence of undershooting in the gate voltage (drive voltage) VG1A of the first transistor 31A can be curbed.

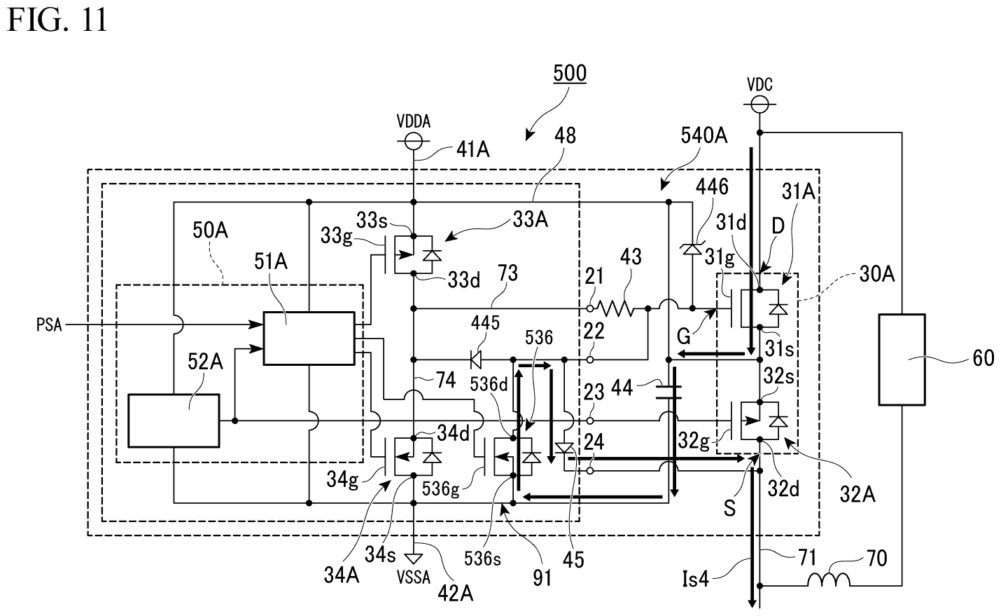

FIG. 11 is a circuit diagram showing part of a semiconductor device 500 of Comparative Example 2. In the description of Comparative Example 2, the same reference signs are suitably applied to constitutions similar to those in the first embodiment, and description may be omitted. As shown in FIG. 11, a drive circuit 540A in the semiconductor device 500 of Comparative Example 2 differs from the drive circuit 440A of the semiconductor device 400 of Comparative Example 1 in having a sixth transistor 536. In the drive circuit 540A, an active mirror clamping circuit is constituted of the sixth transistor 536. The sixth transistor 536 is a normally-off-type transistor. The sixth transistor 536 is an N channel-type field-effect transistor. A drain terminal 536d of the sixth transistor 536 is connected to the gate terminal 31g of the first transistor 31A and the anode of the diode 445. A source terminal 536s of the sixth transistor 536 is connected to the ground 91. A gate terminal 536g of the sixth transistor 536 is connected to the switching circuit unit 51A. The sixth transistor 536 is switched between the ON state and the OFF state by the switching circuit unit 51A.

In the drive circuit 540A of Comparative Example 2, the gate terminal 31g of the first transistor 31A and the ground 91 can be short-circuited by causing the sixth transistor 536 to be in the ON state. For this reason, by causing the sixth transistor 536 to be in the ON state in accordance with the timing when the transistor circuit 30B on the lower side is switched to the OFF state, the potential of the gate terminal 31g of the first transistor 31A can be caused to be the reference potential VSS, and the occurrence of undershooting in the gate voltage VG1A can be curbed. However, as shown in FIG. 11, when the power source VDC is started up, a current Is4 flowing from the first transistor 31A to the ground 91 flows in the body diode of the sixth transistor 536 having a resistance value smaller than the resistance values of the resistive element 43 and the diode 445 in the opposite direction and flows from the diode 45 to the source terminal S of the transistor circuit 30A. For this reason, the current Is4 does not flow in the elements having a high resistance value so that the current Is4 cannot be reduced. Therefore, when the power source VDC is started up, generation of an inrush current cannot be curbed. In this manner, in the case of simply curbing the occurrence of undershooting, it is conceivable to provide an active mirror clamping circuit as in Comparative Example 2. However, in such a case, there is a problem in that generation of an inrush current cannot be curbed.

Regarding the foregoing problems, according to the first embodiment, the fifth transistor 35A is disposed between the gate terminal 31g of the first transistor 31A and the fourth transistor 34A. For this reason, as shown in FIG. 6, differently from the sixth transistor 536 of Comparative Example 2, the current Is1 flowing when the power source VDC is started up does not directly flow to the fifth transistor 35A from the ground 91. Accordingly, during a period until the current Is1 flows to the source terminal S of the transistor circuit 30A after flowing from the first transistor 31A to the ground 91, the current Is1 can be reduced by disposing a resistive element such as the resistive element 43. Therefore, when the power source VDC is started up, generation of an inrush current can be curbed. As above, according to the first embodiment, while the occurrence of undershooting in the gate voltage VG1A of the first transistor 31A is curbed, generation of an inrush current can also be curbed.

In addition, according to the first embodiment, when the voltage of the power source voltage wiring 48 is higher than the absolute value Vth of the threshold voltage of the first transistor 31A, the control circuit unit 50A causes the second transistor 32A to be in the ON state. When the voltage of the power source voltage wiring 48 is higher than the absolute value Vth of the threshold voltage of the first transistor 31A and when the fourth transistor 34A is in the ON state, the control circuit unit 50A causes the fifth transistor 35A to be in the ON state. For this reason, in a state in which the power source of the drive circuit 40A is turned on and the voltage of the power source voltage wiring 48 has become the constant voltage Vd higher than the absolute value Vth of the threshold voltage of the first transistor 31A, the second transistor 32A is in the ON state at all times. In this state, if the third transistor 33A disposed between the power source voltage wiring 48 and the gate terminal 31g of the first transistor 31A is caused to be in the ON state, the source terminal 31s of the first transistor 31A and the gate terminal 31g are short-circuited via the power source voltage wiring 48, and the normally-on-type first transistor 31A is in the ON state. Accordingly, the transistor circuit 30A is in the ON state. On the other hand, if the fourth transistor 34A disposed between the ground 91 and the gate terminal 31g of the first transistor 31A is caused to be in the ON state, the source terminal 31s of the first transistor 31A and the gate terminal 31g are short-circuited via the ground 91, and the normally-on-type first transistor 31A is in the OFF state. Therefore, the state of the transistor circuit 30A can be easily switched by switching the state of the third transistor 33A and the state of the fourth transistor 34A by the control circuit unit 50A. In addition, since the transistor circuit 30A on the higher side is also in the OFF state at the timing when the transistor circuit 30B on the lower side is switched to the OFF state and the current Is2 described above flows, the fourth transistor 34A is in the ON state. Since the control circuit unit 50A causes the fifth transistor 35A to be in the ON state when the voltage of the power source voltage wiring 48 is higher than the absolute value Vth of the threshold voltage of the first transistor 31A and when the fourth transistor 34A is in the ON state, the fifth transistor 35A is also in the ON state together with the fourth transistor 34A while the current Is2 described above flows. Accordingly, as described above, the occurrence of a voltage fall when the current Is2 flows in the fourth transistor 34A and the fifth transistor 35A can be curbed, and the occurrence of undershooting in the gate voltage VG1A of the first transistor 31A can be preferably curbed.

In addition, according to the first embodiment, the drive circuit 40A includes the resistive element 43 that is disposed between the gate terminal 31g of the first transistor 31A and the third transistor 33A. For this reason, when the third transistor 33A is in the ON state and the power source voltage wiring 48 and the gate terminal 31g of the first transistor 31A are short-circuited, a sudden flow of a current from the power source voltage wiring 48 to the gate terminal 31g can be curbed by the resistive element 43.

In addition, according to the first embodiment, the third transistor 33A and the fourth transistor 34A are connected to each other in series. For this reason, when the power source VDC is started up, the current Is1 which has flowed in the fourth transistor 34A flows to the resistive element 43 that is disposed between the gate terminal 31g of the first transistor 31A and the third transistor 33A. Accordingly, the current Is1 can be reduced by the resistive element 43, and generation of an inrush current can be curbed.

In addition, due to connection between the third transistor 33A and the fourth transistor 34A, the connection terminal 21, of the connection terminals in the semiconductor chip 20A, to which the resistive element 43 is connected can be connected to the ground 91 via the fourth transistor 34A. For this reason, it is easy to make the potential of the connection terminal 21 stable.

In addition, according to the first embodiment, the drive circuit 40A includes the semiconductor chip 20A that has the diode 45, the third transistor 33A, the fourth transistor 34A, the fifth transistor 35A, and the control circuit unit 50A. For this reason, a circuit for normally-off operating the transistor circuit 30A can be easily constituted by connecting the terminal of the semiconductor chip 20A and the transistor circuit 30A. In addition, compared to when each of the diode 45, the third transistor 33A, the fourth transistor 34A, the fifth transistor 35A, and the control circuit unit 50A is provided as an individual element, it is easier to miniaturize the drive circuit 40A in its entirety, and it is easier to reduce the wiring resistance by shortening the length of the wiring connecting the elements to each other.

In addition, according to the first embodiment, the semiconductor device 100 includes the semiconductor package 10A that is constituted of the drive circuit 40A and the transistor circuit 30A sealed in one package. For this reason, the semiconductor package 10A in its entirety can be regarded as one normally-off-type transistor, and various kinds of circuits can be easily constituted. In addition, compared to when each of the drive circuit 40A and the transistor circuit 30A is provided as an individual element, it is easier to miniaturize the semiconductor device 100 in its entirety, and it is easier to reduce the wiring resistance by shortening the length of the wiring connecting the elements to each other.

In addition, according to the first embodiment, the semiconductor device 100 includes the half-bridge circuit 30H having a constitution in which the two transistor circuits 30A and 30B are connected to each other in series. For this reason, even when a worker who manufactures a circuit using the semiconductor device 100 uses any transistor circuit of the transistor circuit 30A and the transistor circuit 30B as the transistor circuit on the higher side, the occurrence of undershooting in the gate voltage and generation of an inrush current can be curbed as described above. In addition, even in a circuit in which the transistor circuit 30A and the transistor circuit 30B are switched between the higher side and the low side, even when any of the transistor circuits 30A and 30B serve as the transistor circuit on the higher side, the occurrence of undershooting in the gate voltage and generation of an inrush current can be curbed as described above.

In addition, according to the first embodiment, the transistor circuit 30A functions as a transistor having the gate terminal 31g of the first transistor 31A, that is, the gate terminal G (drive terminal), the drain terminal D (first terminal) provided in the first transistor 31A, the source terminal S (second terminal) that is the drain terminal 32d (output terminal) of the second transistor 32A, and is connected to the transistor circuit 30B (switching element) in series. The source terminal S is connected to the transistor circuit 30B. The state of the drive circuit 40A is switched such that the path in which the current Is1 flows from the drain terminal D toward the source terminal S through the drive circuit 40A serves as the first path 49a when a voltage is applied between the drain terminal D and the source terminal S before the power source of the semiconductor device 100 is turned on, and the path in which the current Is2 flows from the source terminal S toward the drain terminal D through the drive circuit 40A and the gate terminal 31g of the first transistor 31A serves as the second path 49b when the transistor circuit 30B is in the OFF state during a switching operation of the transistor circuit 30A and the transistor circuit 30B. The resistance value within a range from the source terminal S to the gate terminal 31g of the first transistor 31A in the second path 49b is smaller than the resistance value of the resistive element 43 connected to the gate terminal 31g of the first transistor 31A. For this reason, compared to when the current Is2 flows the resistive element 43, the occurrence of a voltage fall can be curbed during a period until the current Is2 flows to the gate terminal 31g through the second path 49b. Therefore, the occurrence of undershooting in the gate voltage (drive voltage) VG1A of the first transistor 31A can be curbed. In addition, the resistance value in the first path 49a is equal to or larger than the resistance value of the resistive element 43. For this reason, the resistance value of the first path 49a can be caused to be equal to or larger than that of the path in which the resistive element 43 is provided so that the current Is1 flowing in the first path 49a can be reduced. Therefore, when the power source VDC is started up, generation of an inrush current can be curbed.

### Second Embodiment

A second embodiment differs from the first embodiment in that the wiring portion between the third transistor 33A and the fourth transistor 34A is disconnected. In the following description, the same reference signs are suitably applied to constitutions similar to those in the embodiment described above, and description may be omitted.

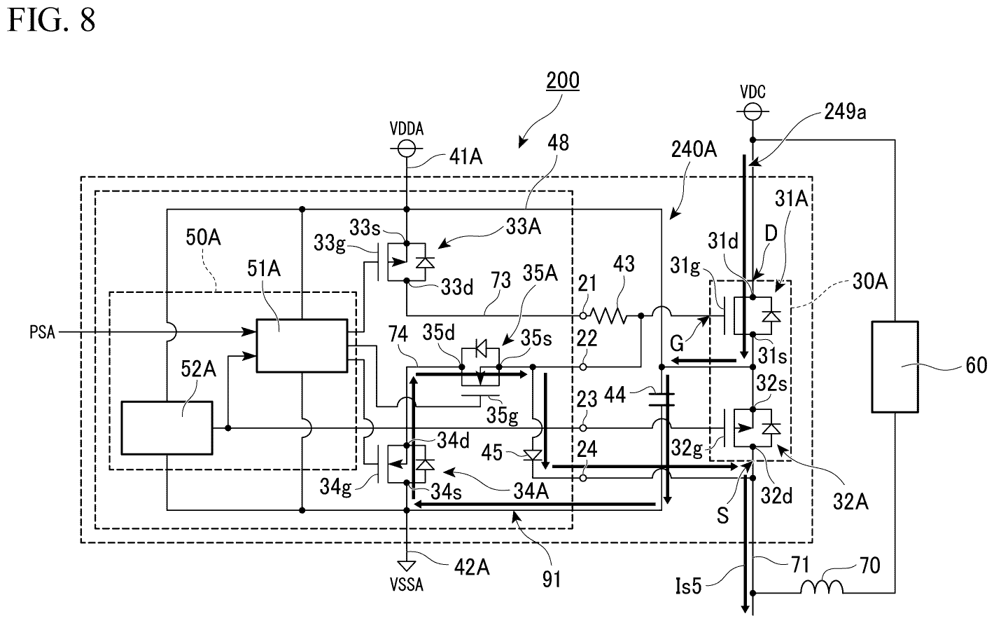

FIG. 8 is a circuit diagram showing part of a semiconductor device 200 of the second embodiment. As shown in FIG. 8, in a drive circuit 240A of the semiconductor device 200, a wiring portion 73 connecting the third transistor 33A and the resistive element 43 and a wiring portion 74 connecting the fourth transistor 34A and the fifth transistor 35A are insulated from each other. For this reason, a current Is5 flowing when the power source VDC is started up flows in the fifth transistor 35A instead of the resistive element 43 after flowing in the first transistor 31A, the capacitor 44, and the fourth transistor 34A in this order. Before the power source of the semiconductor device 200 is turned on, the fifth transistor 35A is in the OFF state. For this reason, according to the second embodiment, the current Is5 flowing when the power source VDC is started up can be extremely reduced by the fifth transistor 35A being in the OFF state. Therefore, generation of an inrush current can be further curbed when the power source VDC is started up.

The current Is5 is a current from the drain terminal D in the transistor circuit 30A toward the source terminal S in the transistor circuit 30A through the drive circuit 240A. The path in which the current Is5 flows serves as a first path 249a. The resistance value in the first path 249a is equal to or larger than the resistance value of the resistive element 43. In the second embodiment, the fifth transistor 35A in the OFF state is included in the first path 249a. The resistance value in the fifth transistor 35A in the OFF state is larger than the resistance value of the resistive element 43. For this reason, in the second embodiment, the resistance value in the first path 249a is larger than the resistance value of the resistive element 43.

Other constitutions of the drive circuit 240A are similar to those of the drive circuit 40A in the first embodiment. Other constitutions of the semiconductor device 200 are similar to those of the semiconductor device 100 in the first embodiment.

### Third Embodiment

A third embodiment differs from the first embodiment in that a second transistor 332A is an N channel-type transistor. In the following description, the same reference signs are suitably applied to constitutions similar to those in the embodiments described above, and description may be omitted.

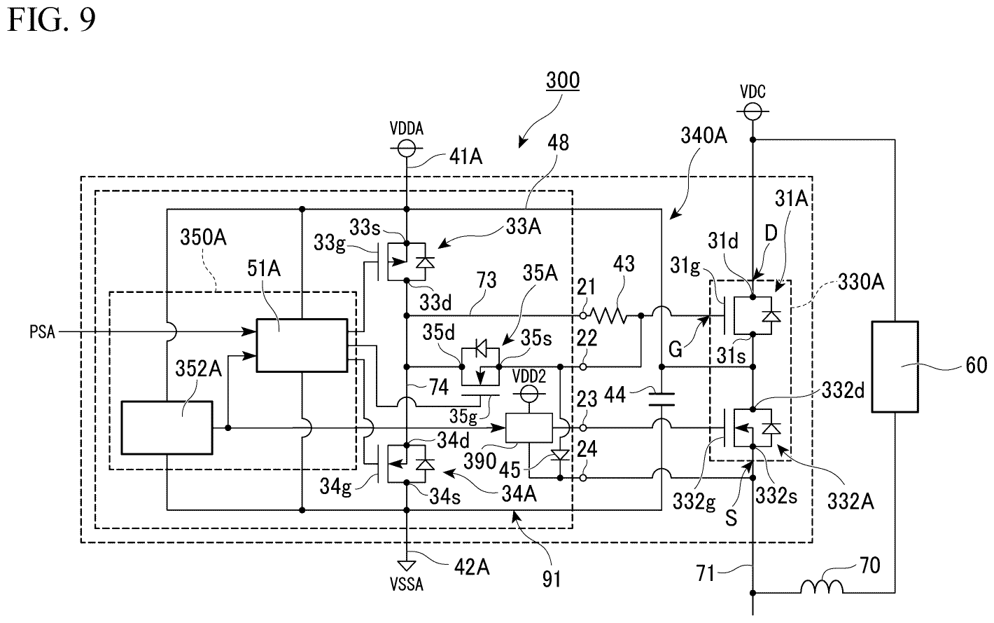

FIG. 9 is a circuit diagram showing part of a semiconductor device 300 of the third embodiment. As shown in FIG. 9, in a drive circuit 340A of the third embodiment, the second transistor 332A of a transistor circuit 330A is an N channel-type field-effect transistor. A drain terminal 332d of second transistor 332A is connected to the source terminal 31s of the first transistor 31A. A source terminal 332s of the second transistor 332A is connected to the wiring portion 71. The cathode of the diode 45 is connected to the source terminal 332s of the second transistor 332A. In the third embodiment, the source terminal 332s of the second transistor 332A is the source terminal S of the transistor circuit 330A.

The drive circuit 340A has a level shifter circuit unit 390. The level shifter circuit unit 390 is connected to a gate terminal 332g and the source terminal 332s of the second transistor 332A. A second power source voltage VDD2 is applied to the level shifter circuit unit 390. The second power source voltage VDD2 is a higher voltage than the power source voltage VDD. In the third embodiment, a voltage comparison circuit unit 352A of a control circuit unit 350A outputs comparison results of the power source voltage VDD to the switching circuit unit 51A and the level shifter circuit unit 390.

When a signal indicating that the power source voltage VDD from the voltage comparison circuit unit 352A has exceeded the absolute value Vth of the threshold voltage of the first transistor 31A is input, the level shifter circuit unit 390 applies the second power source voltage VDD2 to the gate terminal 332g of the second transistor 332A. Accordingly, the second transistor 332A is in the ON state. In the third embodiment, when a signal indicating that the power source voltage VDD has become equal to or higher than the value Vh which is higher than the absolute value Vth of the threshold voltage of the first transistor 31A is input from the voltage comparison circuit unit 352A, the level shifter circuit unit 390 causes the second transistor 332A to be in the ON state by applying the second power source voltage VDD2 to the gate terminal 332g of the second transistor 332A. When the power source voltage VDD is lower than the value Vh, for example, the level shifter circuit unit 390 causes the second transistor 332A to be in the OFF state by short-circuiting the gate terminal 332g and the source terminal 332s of the second transistor 332A.

During a switching operation of the semiconductor device 300, the timing when the state of the second transistor 332A is switched is the same as that when the state of the second transistor 32A according to the first embodiment is switched. In the third embodiment as well, due to switching of the state of each transistor similar to the first embodiment, the occurrence of undershooting in the gate voltage VG1A of the first transistor 31A and generation of an inrush current can be curbed similarly to the embodiments described above.

Other constitutions of the drive circuit 340A are similar to those of the drive circuit 40A according to the first embodiment. Other constitutions of the semiconductor device 300 are similar to those of the semiconductor device 100 according to the first embodiment.

According to at least one of the embodiments described above, the drive circuit is a drive circuit that normally-off drives a transistor circuit which is constituted of a normally-on-type first transistor and a normally-off-type second transistor connected in series. A power source voltage wiring for applying a power source voltage is connected between the first transistor and the second transistor. The drive circuit has a diode in which an anode is connected to a drive terminal of the first transistor and a cathode is connected to an output terminal of the second transistor; a third transistor which is disposed between the power source voltage wiring and the drive terminal of the first transistor; a fourth transistor which is disposed between a ground, having a reference potential that becomes a reference for the power source voltage, and the drive terminal of the first transistor; a fifth transistor which is disposed between the drive terminal of the first transistor and the fourth transistor; and a control circuit unit which switches each of the second transistor, the third transistor, the fourth transistor, and the fifth transistor between an ON state and an OFF state. Accordingly, the occurrence of undershooting in the drive voltage of the first transistor can be curbed.

The first transistor may be any type of transistor as long as it is a normally-on-type transistor. The second transistor may be any type of transistor as long as it is a normally-off-type transistor. The third transistor may be any type of transistor as long as it is disposed between the power source voltage wiring and the drive terminal of the first transistor and the ON/OFF state thereof is switched by the control circuit unit. The fourth transistor may be any type of transistor as long as it is disposed between the ground, having a reference potential that becomes a reference for the power source voltage, and the drive terminal of the first transistor and the ON/OFF state thereof is switched by the control circuit unit. The fifth transistor may be any type of transistor as long as it is disposed between the drive terminal of the first transistor and the fourth transistor and the ON/OFF state thereof is switched by the control circuit unit.

The control circuit unit may have any type of constitution. The control circuit unit may have a constitution in which a voltage applied to the second transistor, the third transistor, the fourth transistor, and the fifth transistor is switched by a switching element such as a transistor, or may be constituted to include a microprocessor or the like. The element included in the semiconductor chip provided in the drive circuit is not particularly limited. The element included in the semiconductor package provided in the semiconductor device is not particularly limited. The semiconductor device may be simply constituted of one semiconductor package. When a switching element is connected in series to a transistor circuit which is constituted of the normally-on-type first transistor and the normally-off-type second transistor according to the embodiment connected in series, the switching element may be any type of switching element. The switching element may be a switching element having a constitution similar to that of the transistor circuit according to the embodiment and may be a switching element having a constitution different from the transistor circuit according to the embodiment.

The drive circuit and the semiconductor device according to the embodiments include forms of the following appendices.

### Appendix 1

A drive circuit normally-off drives a transistor circuit which is constituted of a normally-on-type first transistor and a normally-off-type second transistor connected in series. A power source voltage wiring for applying a power source voltage is connected between the first transistor and the second transistor. The drive circuit includes a diode in which an anode is connected to a drive terminal of the first transistor and a cathode is connected to an output terminal of the second transistor; a third transistor which is disposed between the power source voltage wiring and the drive terminal of the first transistor; a fourth transistor which is disposed between a ground, having a reference potential that becomes a reference for the power source voltage, and the drive terminal of the first transistor; a fifth transistor which is disposed between the drive terminal of the first transistor and the fourth transistor; and a control circuit unit which switches each of the second transistor, the third transistor, the fourth transistor, and the fifth transistor between an ON state and an OFF state.

### Appendix 2

In the drive circuit according to Appendix 1, the control circuit unit causes the second transistor to be in the ON state when the voltage of the power source voltage wiring is higher than an absolute value of a threshold voltage of the first transistor, and causes the fifth transistor to be in the ON state when the voltage of the power source voltage wiring is higher than the absolute value of the threshold voltage of the first transistor and when the fourth transistor is in the ON state.

### Appendix 3

The drive circuit according to Appendix 1 or Appendix 2 further includes a resistive element which is disposed between the drive terminal of the first transistor and the third transistor.

### Appendix 4

In the drive circuit according to Appendix 3, the third transistor and the fourth transistor are connected to each other in series.

### Appendix 5

In the drive circuit according to Appendix 3, a wiring portion connecting the third transistor and the resistive element and a wiring portion connecting the fourth transistor and the fifth transistor are insulated from each other.

### Appendix 6

The drive circuit according to any one of Appendix 1 to Appendix 5 further includes a semiconductor chip which has the diode, the third transistor, the fourth transistor, the fifth transistor, and the control circuit unit.

### Appendix 7

A semiconductor device includes a drive circuit according to any one of Appendix 1 to Appendix 6, and the transistor circuit which is normally-off driven by the drive circuit.

### Appendix 8

The semiconductor device according to Appendix 7 further includes a semiconductor package which is constituted of the drive circuit and the transistor circuit sealed in one package.

### Appendix 9

The semiconductor device according to Appendix 7 or Appendix 8 further includes a half-bridge circuit which is constituted of the two transistor circuits connected to each other in series.

### Appendix 10

In the semiconductor device according to Appendix 7 or Appendix 8, the transistor circuit functions as a transistor having a drive terminal of the first transistor, a first terminal provided in the first transistor, and a second terminal serving as an output terminal of the second transistor and is connected to a switching element in series. The second terminal is connected to the switching element. A state of the drive circuit is switched such that a path in which a current flows from the first terminal toward the second terminal through the drive circuit serves as a first path when a voltage is applied between the first terminal and the second terminal before a power source of the semiconductor device is turned on, and a path in which a current flows from the second terminal toward the first terminal through the drive circuit and the drive terminal of the first transistor serves as a second path when the switching element is in the OFF state during a switching operation of the transistor circuit and the switching element. A resistance value within a range from the second terminal to the drive terminal of the first transistor in the second path is smaller than the resistance value of a resistive element connected to the drive terminal of the first transistor. The resistance value in the first path is equal to or larger than the resistance value of the resistive element.

### Appendix 11

A semiconductor device includes a transistor circuit which is constituted of a normally-on-type first transistor and a normally-off-type second transistor connected in series, and a drive circuit which normally-off drives the transistor circuit. The transistor circuit functions as a transistor having a drive terminal of the first transistor, a first terminal provided in the first transistor, and a second terminal serving as an output terminal of the second transistor and is connected to a switching element in series. The second terminal is connected to the switching element. A state of the drive circuit is switched such that a path in which a current flows from the first terminal toward the second terminal through the drive circuit serves as a first path when a voltage is applied between the first terminal and the second terminal before a power source of the semiconductor device is turned on, and a path in which a current flows from the second terminal toward the first terminal through the drive circuit and the drive terminal of the first transistor serves as a second path when the switching element is in an OFF state during a switching operation of the transistor circuit and the switching element. A resistance value within a range from the second terminal to the drive terminal of the first transistor in the second path is smaller than the resistance value of a resistive element connected to the drive terminal of the first transistor. The resistance value in the first path is equal to or larger than the resistance value of the resistive element.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

The functionality of the elements disclosed herein may be implemented using circuitry or processing circuitry which includes general purpose processors, special purpose processors, integrated circuits, ASICs (“Application Specific Integrated Circuits”), FPGAs (“Field Programmable Gate Arrays”), conventional circuitry and/or combinations thereof which are programmed, using one or more programs stored in one or more memories, or otherwise configured to perform the disclosed functionality. Processors are considered processing circuitry or circuitry as they include transistors and other circuitry therein. The processor may be a programmed processor which executes a program stored in a memory. In the disclosure, the circuitry, units, or means are hardware that carry out or are programmed to perform the recited functionality. The hardware may be any hardware disclosed herein which is programmed or configured to carry out the recited functionality.

What is claimed is:

1. A drive circuitry that normally-off drives a transistor circuitry which is constituted of a normally-on-type first transistor and a normally-off-type second transistor connected in series,
wherein a power source voltage wiring for applying a power source voltage is connected between the first transistor and the second transistor, and
the drive circuitry comprises:
a diode in which an anode is connected to a drive terminal of the first transistor and a cathode is connected to an output terminal of the second transistor,
a third transistor which is disposed between the power source voltage wiring and the drive terminal of the first transistor,
a fourth transistor which is disposed between a ground, having a reference potential that becomes a reference for the power source voltage, and the drive terminal of the first transistor,
a fifth transistor which is disposed between the drive terminal of the first transistor and the fourth transistor, and
a control circuitry which switches each of the second transistor, the third transistor, the fourth transistor, and the fifth transistor between an ON state and an OFF state.

2. The drive circuitry according to claim 1,
wherein the control circuitry
causes the second transistor to be in the ON state when the voltage of the power source voltage wiring is higher than an absolute value of a threshold voltage of the first transistor, and
causes the fifth transistor to be in the ON state when the voltage of the power source voltage wiring is higher than the absolute value of the threshold voltage of the first transistor and when the fourth transistor is in the ON state.

3. The drive circuitry according to claim 1, further comprising:
a resistive element which is disposed between the drive terminal of the first transistor and the third transistor.

4. The drive circuitry according to claim 3,
wherein the third transistor and the fourth transistor are connected to each other in series.

5. The drive circuitry according to claim 3,
wherein a wiring portion connecting the third transistor and the resistive element and a wiring portion connecting the fourth transistor and the fifth transistor are insulated from each other.

6. The drive circuitry according to claim 1, further comprising:
a semiconductor chip which has the diode, the third transistor, the fourth transistor, the fifth transistor, and the control circuitry.

7. A semiconductor device comprising:
a drive circuitry which normally-off drives a transistor circuitry which is constituted of a normally-on-type first transistor and a normally-off-type second transistor connected in series; and
the transistor circuitry which is normally-off driven by the drive circuitry,
wherein a power source voltage wiring for applying a power source voltage is connected between the first transistor and the second transistor,
the drive circuitry has
a diode in which an anode is connected to a drive terminal of the first transistor and a cathode is connected to an output terminal of the second transistor,
a third transistor which is disposed between the power source voltage wiring and the drive terminal of the first transistor,
a fourth transistor which is disposed between a ground, having a reference potential that becomes a reference for the power source voltage, and the drive terminal of the first transistor,
a fifth transistor which is disposed between the drive terminal of the first transistor and the fourth transistor, and
a control circuitry which switches each of the second transistor, the third transistor, the fourth transistor, and the fifth transistor between an ON state and an OFF state.

8. The semiconductor device according to claim 7, further comprising:
a semiconductor package which is constituted of the drive circuitry and the transistor circuitry sealed in one package.

9. The semiconductor device according to claim 7, further comprising:
a half-bridge circuitry which is constituted of the two transistor circuitries connected to each other in series.

10. The semiconductor device according to claim 7,
wherein the transistor circuitry functions as a transistor having a drive terminal of the first transistor, a first terminal provided in the first transistor, and a second terminal serving as an output terminal of the second transistor and is connected to a switching element in series,
the second terminal is connected to the switching element,
a state of the drive circuitry is switched such that
a path in which a current flows from the first terminal toward the second terminal through the drive circuitry serves as a first path when a voltage is applied between the first terminal and the second terminal before a power source of the semiconductor device is turned on, and
a path in which a current flows from the second terminal toward the first terminal through the drive circuitry and the drive terminal of the first transistor serves as a second path when the switching element is in the OFF state during a switching operation of the transistor circuitry and the switching element,
a resistance value within a range from the second terminal to the drive terminal of the first transistor in the second path is smaller than the resistance value of a resistive element connected to the drive terminal of the first transistor, and
the resistance value in the first path is equal to or larger than the resistance value of the resistive element.

11. A semiconductor device comprising:
a transistor circuitry which is constituted of a normally-on-type first transistor and a normally-off-type second transistor connected in series; and
a drive circuitry which normally-off drives the transistor circuitry,
wherein the transistor circuitry functions as a transistor having a drive terminal of the first transistor, a first terminal provided in the first transistor, and a second terminal serving as an output terminal of the second transistor and is connected to a switching element in series,
the second terminal is connected to the switching element,
a state of the drive circuitry is switched such that
a path in which a current flows from the first terminal toward the second terminal through the drive circuitry serves as a first path when a voltage is applied between the first terminal and the second terminal before a power source of the semiconductor device is turned on, and
a path in which a current flows from the second terminal toward the first terminal through the drive circuitry and the drive terminal of the first transistor serves as a second path when the switching element is in an OFF state during a switching operation of the transistor circuitry and the switching element,
a resistance value within a range from the second terminal to the drive terminal of the first transistor in the second path is smaller than the resistance value of a resistive element connected to the drive terminal of the first transistor, and
the resistance value in the first path is equal to or larger than the resistance value of the resistive element.
